(19) United States
(12) Patent Application Publication
(10) Pub. No.: US 2023/0099576 A1
(43) Pub. Date: Mar. 30, 2023

(54) UNIVERSAL INTERFACE

(71) Applicant: Baker Hughes Holdings LLC, Houston, TX (US)

(72) Inventors: Jianjun Jiang, Shanghai (CN); Daniel Zahi Abawi, Gardnerville, NV (US); Guijun Zhang, Shanghai (CN); Chang Lv, Shanghai (CN); Shijia Guo, Shanghai (CN)

(21) Appl. No.: 17/490,771

(22) Filed: Sep. 30, 2021

(51) Int. Cl. H03F 3/45; H03F 3/193; H03G 3/30

(52) U.S. Cl. CPC H03F 3/45475; H03F 3/193; H03G 3/3052

(57) ABSTRACT

An interface circuit includes an input circuit. The input circuit includes a first input pin, a second input pin and a third input pin. The input circuit further includes a first operational amplifier including a first output pin, a first non-inverting input pin electrically coupled to the first input pin via a first impedance and a first switch, and a first inverting input pin coupled to the first output pin. The input circuit also includes a second operational amplifier including a second output pin, a second non-inverting input electrically coupled to the second input pin via a second impedance and a second inverting input pin electrically coupled to the third input pin via a third impedance and a second switch. The first input pin and the second input pin are electrically coupled via a third switch and a fourth impedance.

### BACKGROUND

An operational amplifier (“op-amp”) can transform electrical impedance between a signal circuit and a load circuit. For example, the op-amp can shield the signal circuit from currents (or voltages) generated in the load circuit. An op-amp can be a voltage op-amp or a current op-amp. A voltage op-amp can transfer a voltage from the signal circuit having a high output impedance level to the load circuit with a low input impedance level. A current op-amp can transfer a current from the signal circuit having a low output impedance level to a load circuit with a high input impedance level. The buffer amplifier can prevent the signal source from being affected by voltages/currents that the load may produce.

### SUMMARY

An interface circuit includes an input circuit. The input circuit includes a first input pin, a second input pin and a third input pin. The input circuit further includes a first operational amplifier including a first output pin, a first non-inverting input pin electrically coupled to the first input pin via a first impedance and a first switch, and a first inverting input pin coupled to the first output pin. The input circuit also includes a second operational amplifier including a second output pin, a second non-inverting input electrically coupled to the second input pin via a second impedance and a second inverting input pin electrically coupled to the third input pin via a third impedance and a second switch. The first input pin and the second input pin are electrically coupled via a third switch and a fourth impedance. The second input pin and the third input pin are electrically coupled via a fifth impedance and a fourth switch. The fifth switch is located between the first input pin and a first node where the second switch and the third impedance are coupled.

One or more of the following features can be included in any feasible combination.

In some implementations, the interface circuit further includes an output circuit including a fourth input pin coupled to the first output pin, a fifth input pin coupled to the second output pin, a third output pin, a fourth output pin, a first multiplexer switch, and a plurality of level shifter circuits. The first multiplexer switch is configured to electrically couple one of the fourth input pin to the third output pin via a first level shifter of the plurality of level shifters; the fifth input pin to the third output pin via a direct connector; the fifth input pin to the third output pin via a second level shifter of the plurality of level shifters; and the fifth input pin to the third output pin via a third level shifter of the plurality of level shifters.

In some implementations, the first input pin and the third input pin are coupled to a negative proximity sensor. The first switch and the fifth switch are turned off, and the second switch, the third switch, and the fourth switch are turned on. In some implementations, the first multiplexer switch is configured to electrically couple the fifth input pin to the third output pin via a direct connector. A first voltage signal is generated by the second operational amplifier is transmitted from the second output pin of the input circuit to the third output pin of the output circuit via the direct connector.

In some implementations, the first input pin and the third input pin are coupled to a positive proximity sensor. The first switch and the fifth switch are turned off, and the second switch, the third switch, and the fourth switch are turned on. In some implementations, the first multiplexer switch is configured to electrically couple the fifth input pin to the third output pin via the second level shifter. The second level shifter is configured to generate a second level shifted voltage signal based on a second voltage signal generated by the second operational amplifier. The second level shifted voltage signal is transmitted to the third output pin.

In some implementations, the interface circuit further includes a power supply circuit coupled to the first input pin. The power supply circuit includes a first current source electrically coupled to a voltage source via a sixth switch, and a sixth impedance electrically coupled to the voltage source via a seventh switch. The first current source and the sixth impedance are coupled at a second node, and the second node is electrically coupled to the first input via a tenth switch.

In some implementations, the interface circuit further includes a current supply circuit coupled to the first input pin and the second input pin. The current supply circuit includes a second current source electrically coupled to the first input pin via an eighth impedance and a twelfth switch, and coupled to the ground potential via a ninth switch; and a third current source electrically coupled to the second input pin via a seventh impedance and an eleventh switch and coupled to a ground potential via an eighth switch. In some implementations, the first input pin and the third input pin are coupled to an acceleration sensor and the second input is coupled to a temperature sensor. The first switch, the second switch, the sixth switch, the eighth switch and the tenth switch are turned on, and the third switch, the fourth switch, the fifth switch, seventh switch and the ninth switch are turned off. In some implementations, the first multiplexer switch is configured to electrically couple the fourth input pin to the third output pin via the first level shifter. The first level shifter is configured to generate a first level shifted voltage signal based on a first voltage signal generated by the first operational amplifier. The first level shifted voltage signal is transmitted to the third output pin, and second multiplexer switch is configured to electrically couple the fifth input pin to the fourth output pin.

In some implementations, the first input pin is configured to receive a positive voltage signal relative to the third input pin. The second switch, the third switch, the seventh switch and the tenth switch are turned on, and the first switch, the fourth switch, the fifth switch, sixth switch, eighth switch, the ninth switch, eleventh switch and twelfth switch are turned off. In some implementations, the first multiplexer switch is configured to electrically couple the fourth input pin to the third output pin via the second level shifter. The second level shifter is configured to generate a third level shifted voltage signal based on a third voltage signal generated by the second operational amplifier. The third level shifted voltage signal is transmitted to the third output pin.

In some implementations, the first input pin and the third input pin are coupled to an analog DC (direct current) voltage source configured to generate a voltage signal source configured to apply one of a positive bias or a negative bias to the first input pin relative to the third input pin. The first switch, the fourth switch, the fifth switch, the sixth switch, the eighth switch and the ninth switch are turned off; and the second switch, the third switch, the seventh switch and the tenth switch are turned on. In some implementations, the first multiplexer switch is configured to electrically couple the fifth input pin to the third output pin via the third level shifter. The third level shifter is configured to generate a fourth level shifted voltage signal based on a fourth voltage signal generated by the second operational amplifier, the fourth level shifted voltage signal transmitted to the third output pin. In some implementations, the first multiplexer switch is turned off and the fifth input pin is electrically coupled to the fourth output pin via a direct connector.

In some implementations, the first input pin and the third input pin are coupled to an analog DC (direct current) voltage source configured to apply a positive bias to the first input pin relative to the third input pin. The first switch, the fifth switch, the sixth switch, the eighth switch and the ninth switch are turned off; and the second switch, the third switch, the fourth switch, the seventh switch and the tenth switch are turned on. In some implementations, the first multiplexer switch is configured to electrically couple the fifth input pin to the third output pin via the second level shifter. The second level shifter is configured to generate a fifth level shifted voltage signal based on a fifth voltage signal generated by the second operational amplifier, the fifth level shifted voltage signal transmitted to the third output pin.

In some implementations, the first input pin and the third input pin are coupled to a magnetic pick up sensor. The first switch, the second switch, the third switch, the sixth switch, the eighth switch and the ninth switch are turned off, and the fourth switch, the fifth switch, seventh switch and the tenth switch are turned on. In some implementations, the first multiplexer switch is configured to electrically couple the fifth input pin to the third output pin via the third level shifter. The third level shifter is configured to generate a sixth level shifted voltage signal based on a sixth voltage signal generated by the second operational amplifier. The sixth level shifted voltage signal transmitted to the third output pin.

In some implementations, the first input pin and the third input pin are coupled to a proximity switch. The first switch, the fifth switch, the seventh switch, the eighth switch and the ninth switch are turned off, and the second switch, the third switch, the fourth switch, the sixth switch and the tenth switch are turned on. In some implementations, the first multiplexer switch is configured to electrically couple the fifth input pin to the third output pin via the second level shifter. The second level shifter is configured to generate a seventh level shifted voltage signal based on a seventh voltage signal generated by the second operational amplifier, the seventh level shifted voltage signal transmitted to the third output pin.

In some implementations, the first input pin, the second input pin and the third input pin are coupled to a resistance temperature detector. The first switch, the second switch, the third switch, the fourth switch, the sixth switch, the seventh switch and the tenth switch are turned off; and the fifth switch, the eighth switch, the ninth switch, the eleventh switch and the twelfth switch are turned on. In some implementations, the first multiplexer switch is turned off and the fifth input pin is electrically coupled to the fourth output pin via a direct connector.

A system includes one or more sensors configured to detect one or more operating parameters of an industrial system, an interface circuit and a monitoring system. The interface circuit is configured to couple to the one or more sensors and receive one or more sensor signals. A first sensor signal of the one or more sensor signals is indicative of a first operating parameters of the one or more operating parameters. The interface circuit includes an input circuit including a first input pin, a second input pin and a third input pin. The input circuit also includes a first operational amplifier and a second operational amplifier. The first operational amplifier includes a first output pin, a first non-inverting input pin electrically coupled to the first input pin via a first impedance and a first switch, and a first inverting input pin coupled to the first output pin. The second operational amplifier includes a second output pin, a second non-inverting input electrically coupled to the second input pin via a second impedance, and a second inverting input pin electrically coupled to the third input pin via a third impedance and a second switch. The first input pin and the second input pin are electrically coupled via a third switch and a fourth impedance. The second input pin and the third input pin are electrically coupled via a fifth impedance and a fourth switch, and a fifth switch is located between the first input pin and a first node where the second switch and the third impedance are coupled. The monitoring system is configured to receive one or more conditioned signals from the interface circuit. A first conditioned signal of the one or more conditioned signal is indicative of a first sensor signal.

In some implementations, the interface circuit further includes an output circuit that includes a fourth input pin coupled to the first output pin, a fifth input pin coupled to the second output pin, a third output pin, a fourth output pin, a first multiplexer switch, and a plurality of level shifter circuits. The first multiplexer switch is configured to electrically couple one of the fourth input pin to the third output pin via a first level shifter of the plurality of level shifters; the fifth input pin to the third output pin via a direct connector; the fifth input pin to the third output pin via a second level shifter of the plurality of level shifters; and the fifth input pin to the third output pin via a third level shifter of the plurality of level shifters.

A method includes detecting, by one or more sensors, one or more operating parameters of an industrial system. The method also includes receiving, by an interface circuit coupled to the one or more sensors, one or more sensor signals from the one or more sensors. A first sensor signal of the one or more signals is indicative of a first operating parameters of the one or more operating parameters. The interface circuit includes an input circuit including a first input pin, a second input pin and a third input pin. The input circuit also includes a first operational amplifier and a second operational amplifier. The first operational amplifier includes a first output pin, a first non-inverting input pin electrically coupled to the first input pin via a first impedance and a first switch, and a first inverting input pin coupled to the first output pin. The second operational amplifier includes a second output pin, a second non-inverting input electrically coupled to the second input pin via a second impedance, and a second inverting input pin electrically coupled to the third input pin via a third impedance and a second switch. The first input pin and the second input pin are electrically coupled via a third switch and a fourth impedance. The second input pin and the third input pin are electrically coupled via a fifth impedance and a fourth switch, and a fifth switch is located between the first input pin and a first node where the second switch and the third impedance are coupled. The method further includes providing, by the interface circuit, one or more conditioned signals to a monitoring system. A first conditioned signal of the one or more conditioned signal is indicative of a first sensor signal.

These and other capabilities of the disclosed subject matter will be more fully understood after a review of the following figures, detailed description, and claims.

### BRIEF DESCRIPTION OF THE FIGURES

These and other features will be more readily understood from the following detailed description taken in conjunction with the accompanying drawings, in which:

FIG. 1 illustrates an exemplary schematic of an interface circuit configured to act as a liaison between multiple sensors at an industrial site and a monitoring system;

FIG. 2 illustrates an equivalent circuit of an exemplary operational amplifier;

FIG. 3 illustrates an exemplary input circuit of the interface circuit in FIG. 1;

FIG. 4 illustrates an exemplary output circuit of the interface circuit in FIG. 1;

FIG. 5 illustrates an exemplary configuration of the interface circuit in FIG. 1 configured to couple a negative proximity sensor to the monitoring system;

FIG. 6 illustrates an exemplary configuration of the interface circuit in FIG. 1 configured to couple a positive proximity sensor to the monitoring system;

FIG. 7 illustrates an exemplary configuration of the interface circuit in FIG. 1 configured to couple a dual output sensor that includes an acceleration sensor and a temperature sensor to the monitoring system;

FIG. 8 illustrates an exemplary configuration of the interface circuit in FIG. 1 configured to couple an analog signal source to the monitoring system;

FIG. 9 illustrates an exemplary configuration of the interface circuit in FIG. 1 configured to couple another analog signal source to the monitoring system;

FIG. 10 illustrates an exemplary configuration of the interface circuit in FIG. 1 configured to couple a thermocouple sensor to the monitoring system;

FIG. 11 illustrates an exemplary configuration of the interface circuit in FIG. 1 configured to couple an exemplary analog signal source to the monitoring system;

FIG. 12 illustrates an exemplary configuration of the interface circuit in FIG. 1 configured to couple a magnetic pick up sensor to the monitoring system;

FIG. 13 illustrates an exemplary configuration of the interface circuit in FIG. 1 configured to couple a proximity switch sensor to the monitoring system; and

FIG. 14 illustrates an exemplary configuration of the interface circuit in FIG. 1 configured to couple a 3-wire resistance temperature detector (RTD) to the monitoring system.

### DETAILED DESCRIPTION

An industrial site (e.g., oil and gas industrial site) can include multiple sensors that can detect the operation parameters of the industrial site. A monitoring system can couple to a sensor and receive the signal associated with the detected operating parameters from the sensor. Different types of sensors can generate signals with different characteristics. For example, sensors can generate an alternating current (AC) signal or a direct current (DC) signal. Additionally, the amplitude of the input signal can vary from a small value (e.g., millivolts) to a large value (e.g., volts). Typically, different monitoring systems are needed to detect the signal of different sensors. Having multiple monitoring systems for an industrial site can be expensive and cumbersome. In some implementations of the current subject matter, an interface circuit is described that can act as a liaison between multiple sensors and the monitoring system. The monitoring systems can include one or more analog-to-digital-converters (ADCs) that can receive detection signals from the sensors. The ADCs can have predetermined specification for the characteristics of the detection signal (e.g., voltage range, voltage amplitudes, etc., associated with the detection signal). The interface circuit can modify the detection signals from the sensors to generate a conditioned output signal that meet the specifications of the ADCs.

The interface circuit can include one or more of voltage sources, current sources, operational amplifiers, switches (e.g., photo-MOS, photo-MOSFETs, etc.) and level shifters. A switch can be switched on or off, for example, by illuminating the switch with electromagnetic radiation (e.g., visible light). In some implementations, the interface circuit can be configured to connect a given target sensor(s) to the monitoring system by selectively switching a first set of switches on. For example, for a given target sensor, electromagnetic radiation can be illuminated of the first set of switches. This can render the interface circuit as a liaison between the given target sensor and the monitoring system. The interface circuit can be reconfigured at act as a liaison between a second sensor and the monitoring system by selectively switching a second set of switches on. In some implementations, the interface circuit can include three input pins configured to receive detection signals from one or more sensors in the industrial site, and two output pins configured to transfer output signals to one or more ADCs in the monitoring system. In some implementations, the output signals generated by the interface circuits can have amplitude values within a predetermined range of values (e.g., values suitable for the ADCs) that may not be effected by the sensor from which the detection signal(s) is received. The interface can also allow for coupling multiple sensors to the ADC. This can allow for transfer of multiple sensor signals to the ADCs (e.g., simultaneously) that can result in an increased throughput. These characteristics can render the interface suitable for coupling various sensors in the industrial site to ADCs (which can digitize the detection signal from further processing by the monitoring system).

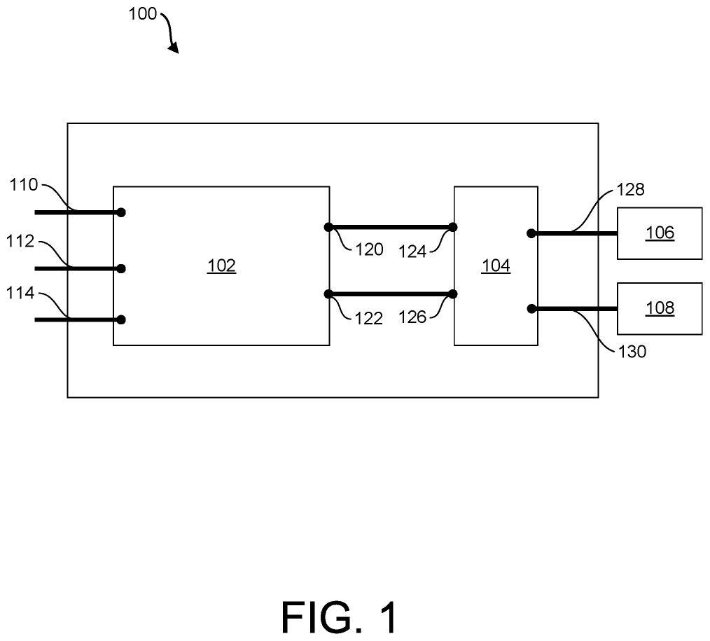

FIG. 1 illustrates an exemplary schematic of an interface circuit 100 configured to act as a liaison between multiple sensors at an industrial site and a monitoring system. The interface circuit 100 includes an input circuit 102 and an output circuit 104. The input circuit 102 includes three input pins (e.g., a first input pin 110, a second input pin 112 and a third input pin 114) and two output pins (e.g., first output pin 120, second output pin 122). The output circuit 104 includes two input pins (e.g., fourth input pin 124, fifth input pin 126) and two output pins (e.g., third output pin 128 and fourth output pin 130). The input circuit 102 can receive sensor signal(s) via one or more of the first input pin 110, the second input pin 112 and the third input pin 114 (e.g., the input pins can be configured to electrically couple with the sensor(s)). The input circuit 102 can include multiple resistors, switches, voltage sources and current sources. In some implementations, the voltage/current sources in the input circuit 102 can provide power to the sensor(s) (e.g., to render the sensor(s) operational).

The input circuit 102 can be reconfigurable. For example, switches in the input circuit 102 can be switched on/off based on the sensor(s) coupled to the first input pin 110, the second input pin 112 and the third input pin 114. Based on the configuration of the input circuit 102, an intermediary signal which is representative of the sensor signal(s) can be outputted via the first output pin 120 and/or the second output pin 122. Output circuit 104 can receive the intermediary signal from the input circuit 102 and output one or more conditioned signals via the third output pin 128 and/or fourth output pin 130. The conditioned signal(s) can be received and digitized by a first ADC 106 and/or a second ADC 108 in the monitoring system for further processing.

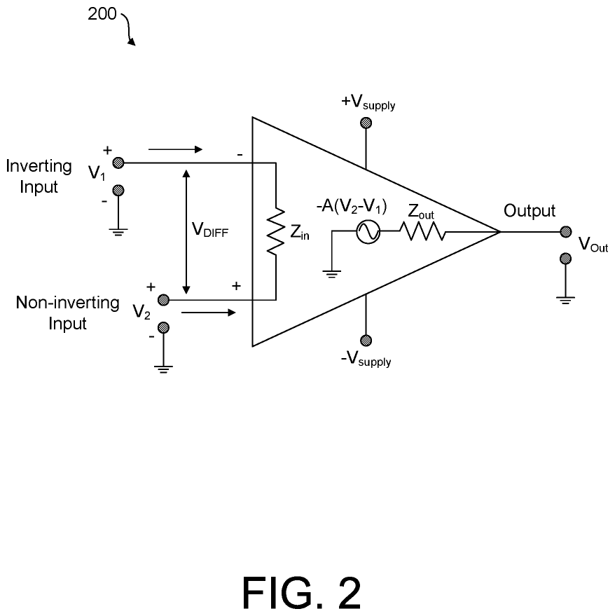

FIG. 2 illustrates an equivalent circuit of an exemplary operational amplifier. The op-amp can include an inverting input that can receive an inverting input (V1), and a non-inverting input that can receive a non-inverting input (V2). The op-amp can also include an output pin Vout that transmits an output signal. In some implementations, the output signal can be proportional to the difference between the inverting and non-inverting inputs (e.g., when the output is electrically connecting to the non-inverting input via an impedance (e.g., a resistor, a capacitor, an inductor, or a combination thereof)). In some implementations, the output signal can be inversely proportional to the input signal (e.g., when the output is electrically connecting to the inverting input via an impedance (e.g., a resistor)). In some implementations, an impedance looking into the op-amp across the inverting and non-inverting inputs can be very high. In some implementations, current flowing into the op-amp via the inverting and non-inverting inputs can be very small (e.g., zero). In some implementations, the op-amp with a feedback will try to adjust the output voltage such that voltages at the inverting and the non-inverting inputs are the same. Based on the aforementioned properties of the op-amp and the desirable operation of the op-amp, values and arrangement of impedances in the feedback circuit can be determined. In some implementations, the input circuit 102 can include a voltage follower circuit (e.g., output signal is the same as in the input signal), a non-inverter circuit (e.g., output signal is directly proportional to the input signal), an inverter circuit (e.g., output signal is inversely proportional to the input signal) and the like.

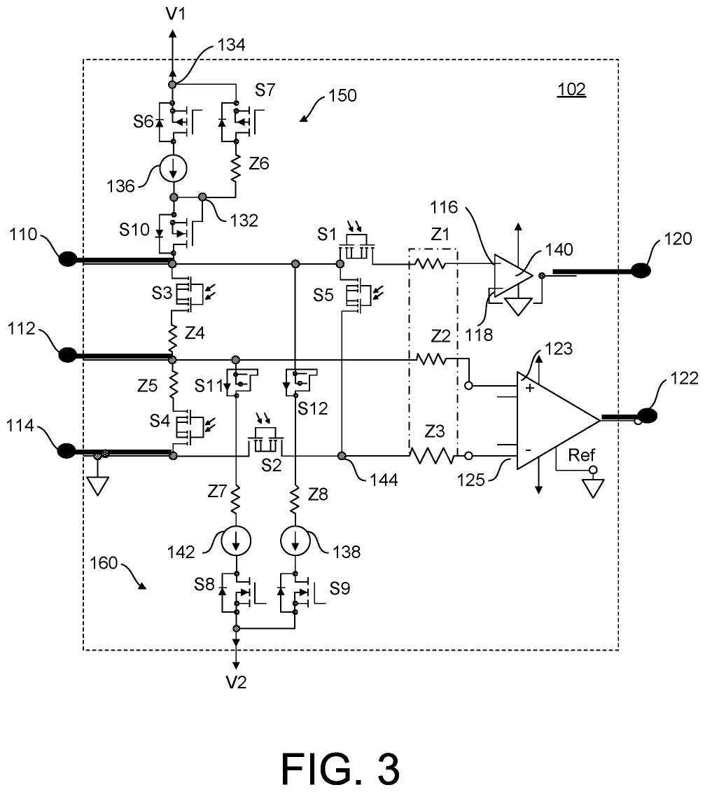

FIG. 3 illustrates an exemplary input circuit 102 that includes impedances, switches, operational amplifiers, current sources and voltage sources. The input circuit 102 includes three input pins (e.g., a first input pin 110, a second input pin 112 and a third input pin 114) and two output pins (e.g., a first output pin 120 and a second output pin 122). One or more of the input pins can be coupled to one or more sensors (e.g., at an industrial site) and can receive signal(s) indicative of a detected operating parameter(s).

The first operational amplifier 140 includes a first output pin 120, a first non-inverting input pin 116 electrically coupled to the first input pin 110 via a first impedance Z1 and a first switch S1. Switching the switch S1 on can establish an electrical connection between the first input pin 110 and the first non-inverting input pin 116. Switching the switch S1 off can electrically disconnect the first input pin 110 and the first non-inverting input pin 116. The first operational amplifier 140 also includes a first inverting input pin 118 coupled to the first output pin 120 by a feedback loop. The second operational amplifier 142 includes a second output pin 122, a second non-inverting input 123 electrically coupled to the second input pin 112 via a second impedance Z2. The second operational amplifier 142 also includes a second inverting input pin 125 electrically coupled to the third input pin 114 via a third impedance Z3 and a second switch S2. Switching the switch S2 on can establish an electrical connection between the third input pin 114 and the second inverting input pin 125. Switching the switch S2 off can electrically disconnect the third input pin 114 and the second inverting input pin 125.

The first input pin 110 and the second input pin 112 can be electrically coupled via a third switch S3 and a fourth impedance Z4. Switching the switch S3 on can establish an electrical connection between the first input pin 110 and the second input pin 112. Switching the switch S3 off can electrically disconnect the first input pin 110 and the second input pin 112. The second input pin 112 and the third input pin 114 can be electrically coupled via a fifth impedance Z5 and a fourth switch S4. Switching the fourth switch S4 on can establish an electrical connection between the second input pin 112 and the third input pin 114. Switching the fourth switch S4 off can electrically disconnect the second input pin 112 and the third input pin 114. An electrical connection can be established between the first input pin 110, the second input pin 112 and the third input pin 114 by switching on both the third switch S3 and the fourth switch S4.

A fifth switch S5 is located between the first input pin 110 and a first node 144 located between the second switch S2 and the third impedance Z3 (e.g., where the second switch S2 and the third impedance Z3 are coupled). Switching the fifth switch S5 on can establish an electrical connection between the first input pin 110 and a first node 144. Switching the fifth switch S5 off can electrically disconnect the first input pin 110 and a first node 144.

The input circuit 102 can include a power supply circuit 150 coupled to the first input pin 110. The power supply circuit 150 can be switched on or off (e.g., by switching on or off one or more switches included in the power supply circuit 150). In some implementations, the power supply circuit 150 can supply power to a sensor coupled to the first input pin 110 (e.g., Injector Control Pressure (ICP) sensors, Integrated Electronics Piezo-Electric (IEPE) sensor, etc.). In some implementations, the power supply circuit 150 can be coupled to a voltage source V1, and can include three switches and a current source. The power supply circuit 150 can include two nodes that can be electrically connected via two paths. For example, a second node 132 and a third node 134 (which is coupled to a voltage source V1) can be electrically connected via a first electrical path that includes a sixth switch S6 and a first current source 136. The second node 132 and third node 134 can also be connected via a second electrical path that includes a seventh switch S7 and a sixth impedance Z6. The second node 132 is electrically coupled to the first input pin 110 via a tenth switch S10 (located between the second node 132 and the first input pin 110).

The electrical connection between the power supply circuit 150 and the first input pin 110 can be established by switching the tenth switch S10 on, and can be disconnected by switching the tenth switch S10 off. A given electrical path in the power supply circuit 150 can be selectively activated. For example, the first electrical path can be selectively activated by switching the sixth switch S6 and the tenth switch S10 on, and switching the seventh switch S7 off Alternately, the second electrical path can be selectively activated by switching the sixth switch S6 off and switching the seventh switch S7 and the tenth switch S10 on.

The input circuit 102 can include a current supply circuit 160 coupled to the first input pin 110 and the second input pin 112. In some implementations, the current supply circuit 160 can be coupled to a voltage source V2 that can be electrically coupled to the first input pin 110 via a first electrical path and can be electrically coupled to the second input pin 112 via a second electrical path. The first electrical path can include a second current source 138 electrically coupled to the first input pin 110 via an eighth impedance Z8 and a twelfth switch S12. The second current source 138 is electrically coupled to the voltage source V2 via a ninth switch S9. The second electrical path can include a third current source 142 electrically coupled to the second input pin 112 via a seventh impedance Z7 and an eleventh switch S11. The third current source 142 is electrically coupled to the voltage source V2 via an eighth switch S8. In some implementations, electrical connection of the first electrical path and the second electrical path to the first input pin 110 and the second input pin 112, respectively, can be independently activated. For example, by switching the ninth switch S9 and the twelfth switch S12 on, the first input pin 110 can be electrically connected to the voltage source V2 via the eighth impedance Z8 and the second current source 138. By switching the eighth switch S8 and the eleventh switch S11 on, the second input pin 112 can be electrically connected to the voltage source V2 via seventh impedance Z7 and the third current source 142. The current supply circuit 160 is disconnected from the first input pin 110 and the second input pin 112 (e.g., by switching the eleventh switch S11 and the twelfth switch S12 off).

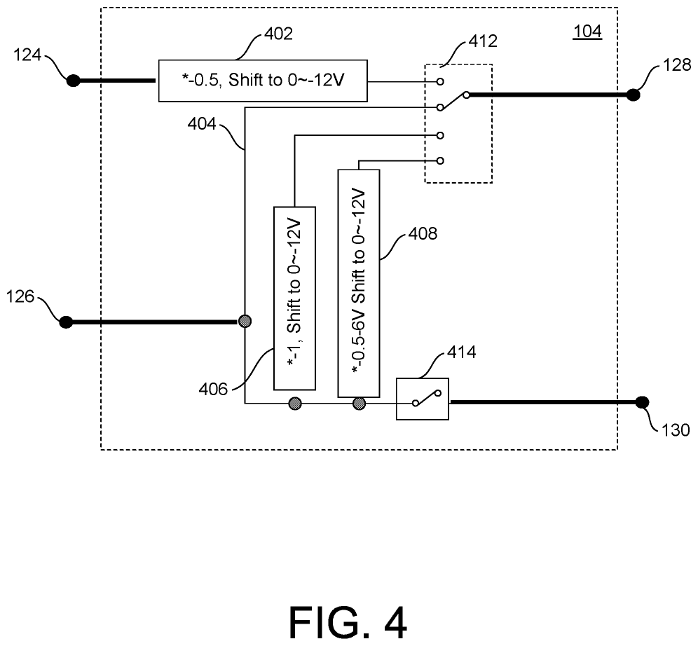

FIG. 4 illustrates an exemplary output circuit 104 that serve as a liaison between the input circuit 102 and a monitoring system (e.g., which can include one or more ADCs). The output circuit 104 can receive the intermediary output signal generated the input circuit 102, modify the intermediary output signal and provide the modified signal (or conditioned signal) to one or more ADCs. For example, the modification of the intermediary output signal can be based on the type of sensor(s) coupled to the input circuit 102. For example, the value of the output signal can be normalized to a predetermined voltage range associated with the acceptable input voltage values of the ADC(s). In some implementations, the output circuit 104 can include multiple level shifters that can modify the voltage value of the intermediary output signal from the input circuit 102 (e.g., each level shifter can simultaneously modify the output signal and generate a level shifted signal). The output circuit 104 can include one or more relay switches that can select the level shifted signal (e.g., by selecting the level shifter) and provide the selected level shifted signal to the ADC in the monitoring system.

As illustrated in FIG. 4, the output circuit 104 includes the fourth input pin 124 that can be coupled to the first output pin 120 and the fifth input pin 126 that can be coupled to the second output pin 122. The output circuit 104 can also include a third output pin 128 and a fourth output pin 130 that can be coupled to a first ADC and a second ADC, respectively, in the monitoring system. The output circuit 104 can also include a plurality of level shifter circuits that can receive a first intermediary output signal via the first output pin 120 and the fourth input pin 124, or a second intermediary output signal via the second output pin 122 and the fifth input pin 126. The output circuit 104 can include a first multiplexer switch 412 that can select the level shifted signal to be transmitted via the third output pin 128. For example, the first multiplexer switch 412 can be configured to electrically couple one of (a) the fourth input pin 124 to the third output pin 128 via a first level shifter 402 of the plurality of level shifters, (b) the fifth input pin 126 to the third output pin 128 via a direct connector 404, (c) the fifth input pin 126 to the third output pin via a second level shifter 406 of the plurality of level shifters, or (d) the fifth input pin 126 to the third output pin via a third level shifter 408 of the plurality of level shifters. The output circuit 104 can include a second multiplexer switch 414 that can switch the electrical coupling between fifth input pin 126 (coupled to the second output pin 122) and the fourth output pin 130 on or off.

The first level shifter 402 can generate a level shifted voltage signal based on a voltage signal received via the fourth input pin 124. For example, the first level shifter 402 can generate the level shifted voltage signal by multiplying the received voltage signal by −0.5 and normalizing the resulting value to a value between 0 Volt and −12 Volt. The second level shifter 406 can generate a level shifted voltage signal based on a voltage signal received via the fifth input pin 126. For example, the second level shifter 406 can generate the level shifted voltage signal by multiplying the received voltage signal by −1 and normalizing the resulting value to a value between 0 Volt and −12 Volts. The third level shifter 408 can generate a level shifted voltage signal based on a voltage signal received via the fifth input pin 126. For example, the third level shifter 408 can generate the level shifted voltage signal by multiplying the received voltage signal by −0.5 and subtracting 6, and normalizing the resulting value to a value between 0 Volt and −12 volt.

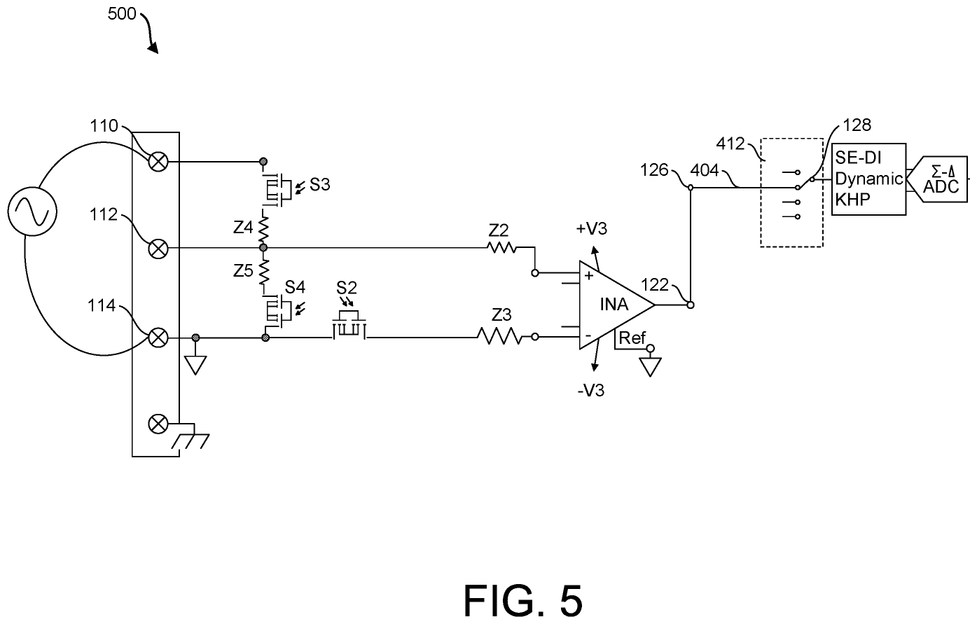

FIG. 5 illustrates an exemplary configuration 500 of the interface circuit 100 configured to couple a negative proximity sensor to the monitoring system. In this implementation of the interface circuit, the first input pin 110 and the third input pin 114 are coupled to a negative proximity sensor (e.g., configured to apply a negative bias to the first input pin 110 relative to the third input pin 114). The power supply circuit 150 is disconnected from the first input pin 110 (e.g., by switching the tenth switch S10 off) and the current supply circuit 160 is disconnected from the first input pin 110 and the second input pin 112 (e.g., by switching the eleventh switch S11 and the twelfth switch S12 off). Furthermore, the first switch S1 and the fifth switch S5 are turned off, and the second switch S2, the third switch S3, and the fourth switch S4 are turned on.

The output circuit 104 can be reconfigured to modify the intermediate output signal of the input circuit 102 coupled to the negative proximity sensor. For example, the first multiplexer switch 412 can be configured to electrically couple the fifth input pin 126 to the third output pin 128 via a direct connector 404 (e.g., a low-impedance wire). This can allow a first voltage signal generated by the second operational amplifier 142 to be transmitted from the second output pin 122 of the input circuit 102 to the third output pin 128 of the output circuit 104 via fifth input pin 126 and the direct connector. The second multiplexer switch 414 can be configured to be switched off and disconnect the fifth input pin 126 from the fourth output pin 130.

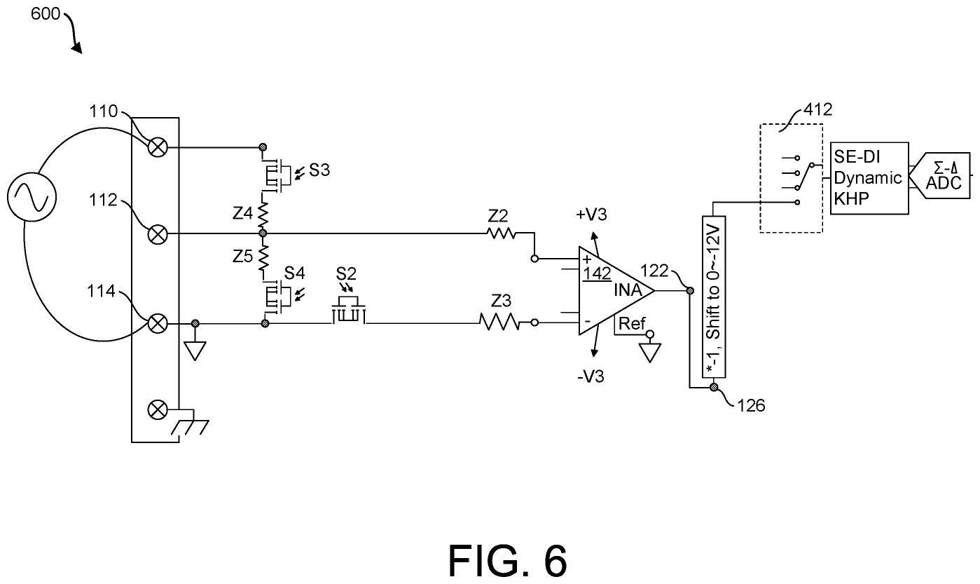

FIG. 6 illustrates an exemplary configuration 600 of the interface circuit 100 configured to couple a positive proximity sensor to the monitoring system. In some implementation of the configuration 600, the first input pin 110 and the third input pin 114 are coupled to a positive proximity sensor (e.g., configured to apply a positive bias to the first input pin 110 relative to the third input pin 114). The power supply circuit 150 is disconnected from the first input pin 110 (e.g., by switching the tenth switch S10 off) and the current supply circuit 160 is disconnected from the first input pin 110 and the second input pin 112 (e.g., by switching the eleventh switch S11 and the twelfth switch S12 off). Furthermore, the first switch S1 and the fifth switch S5 are switched off (not illustrated in FIG. 6), and the second switch S2, the third switch S3, and the fourth switch S4 are switched on.

The output circuit 104 can be reconfigured to modify the intermediate output signal of the input circuit 102 coupled to the positive proximity sensor. For example, the first multiplexer switch 412 can be configured to electrically couple the fifth input pin 126 to the third output pin via the second level shifter 406. The second level shifter 406 is configured to generate a second level shifted voltage signal (e.g., as described above) based on a second voltage signal generated by the second operational amplifier 142 at the second output pin 122. The second level shifted voltage signal is transmitted to the third output pin 128. The second multiplexer switch 414 can be configured to be switched off and disconnect the fifth input pin 126 with the fourth output pin 130.

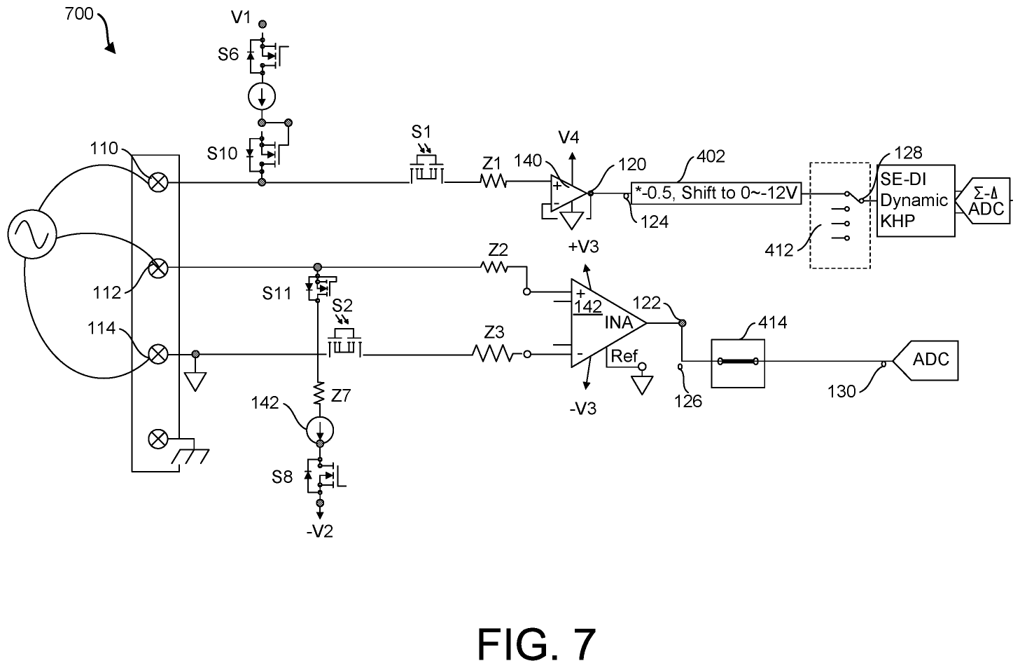

FIG. 7 illustrates an exemplary configuration 700 of the interface circuit 100 configured to couple a dual output sensor that includes an acceleration sensor (e.g., ICP sensor, IEPE sensor, etc.) via first input pin 110 and to couple a temperature sensor via third input pin 114 to the monitoring system. In some implementations, the signal generated by the acceleration sensor can have a large value (e.g. greater than 20 volts). In some implementations, the power supply circuit 150 is connected to the input circuit 102 by switching the tenth switch S10 on. The first electrical path in the power supply circuit 150 is selectively activated by switching the sixth switch S6 on and switching the seventh switch S7 off (which deactivates the second electrical path in the power supply circuit 150). In some implementations, the power supply circuit 150 can provide constant current to the acceleration sensor via the first input pin 110. The current supply circuit 160 is connected to the input circuit 102 by switching the eleventh switch S11 on. The second electrical path in the current supply circuit 160 is selectively activated by switching the eighth switch S8 on and switching the twelfth switch S12 and ninth switch S9 off (which deactivates the first electrical path in the current supply circuit 160). Furthermore, the first switch S1 and the second switch S2 are switched on, and the third switch S3, the fourth switch S4, and the fifth switch S5 are switched off (not shown in FIG. 7).

The output circuit 104 can be reconfigured to modify the intermediate output signal of the input circuit 102 coupled to the ICP/IEPE sensor and temperature sensor. For example, the first multiplexer switch 412 is configured to electrically couple the third input pin 124 to the third output 128 pin via the first level shifter 402. The first level shifter 402 is configured to generate a first level shifted voltage signal (e.g., as described above) based on a first voltage signal generated by the first operational amplifier 140 (e.g., at the first output pin 120). The first level shifted voltage signal is transmitted to the third output pin 128. The second multiplexer switch 414 is configured to electrically couple the fifth input pin 126 to the fourth output pin 130 pin. .

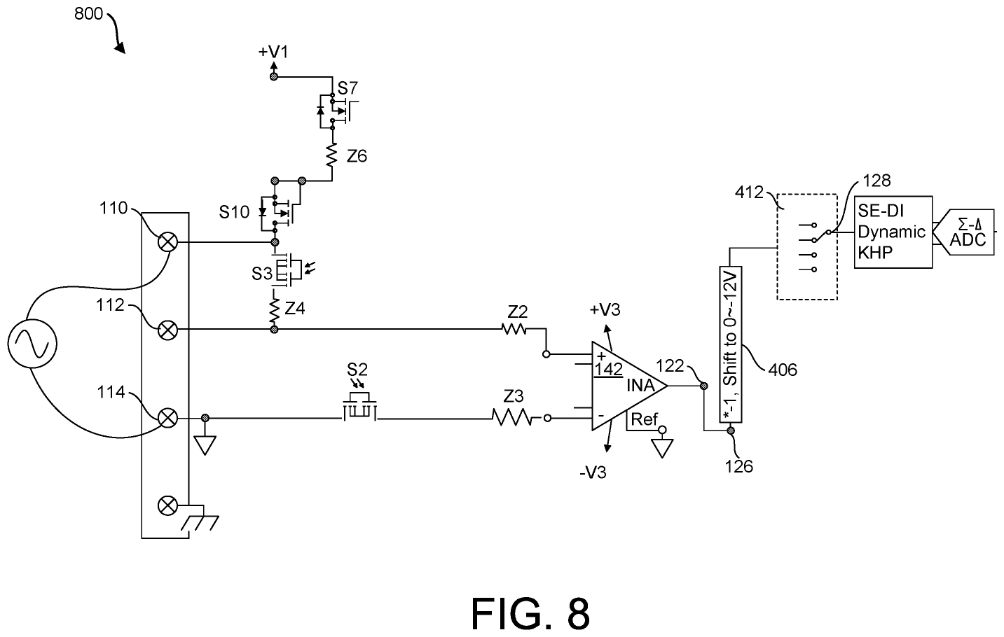

FIG. 8 illustrates an exemplary configuration 800 of the interface circuit 100 configured to couple an analog voltage signal source (e.g., a transmitter, a programmable logical controller (PLC), a distributed control system (DCS), etc.) to the monitoring system. In some implementations, the first input pin 110 and the third input pin 114 are coupled to a DC (direct current) voltage source (e.g., included in analog signal source) configured to apply a voltage bias (e.g., a positive bias) to the first input pin 110 relative to the third input pin 114. In some implementations, the power supply circuit 150 is connected to the input circuit 102 by switching on the tenth switch S10. The second electrical path in the power supply circuit 150 is selectively activated by switching the seventh switch S7 on and switching the sixth switch S6 off (which deactivates the first electrical path in the power supply circuit 150). The current supply circuit 160 is disconnected from the first input pin 110 and the second input pin 112 (e.g., by switching the eleventh switch S11 and the twelfth switch S12 off).. Furthermore, the second switch S2, and the third switch S3 are switched on, and the first switch S1, the fourth switch S4, the fifth switch S5, eighth switch S8, and the ninth switch S9 (not shown in FIG. 8) are switched off.

The output circuit 104 can be reconfigured to modify the intermediate output signal of the input circuit 102 coupled to the analog voltage signal source. For example, the first multiplexer switch 412 can be configured to electrically couple the fifth input pin 126 to the third output pin 128 via the second level shifter 406. The second level shifter 406 is configured to generate a third level shifted voltage signal (e.g., as described above) based on a third voltage signal generated by the second operational amplifier 142 (e.g., at the second output pin 122). The third level shifted voltage signal is transmitted to the third output pin 128. The second multiplexer switch 414 can be configured to be switched off and disconnect the fifth input pin 126 from the fourth output pin 130.

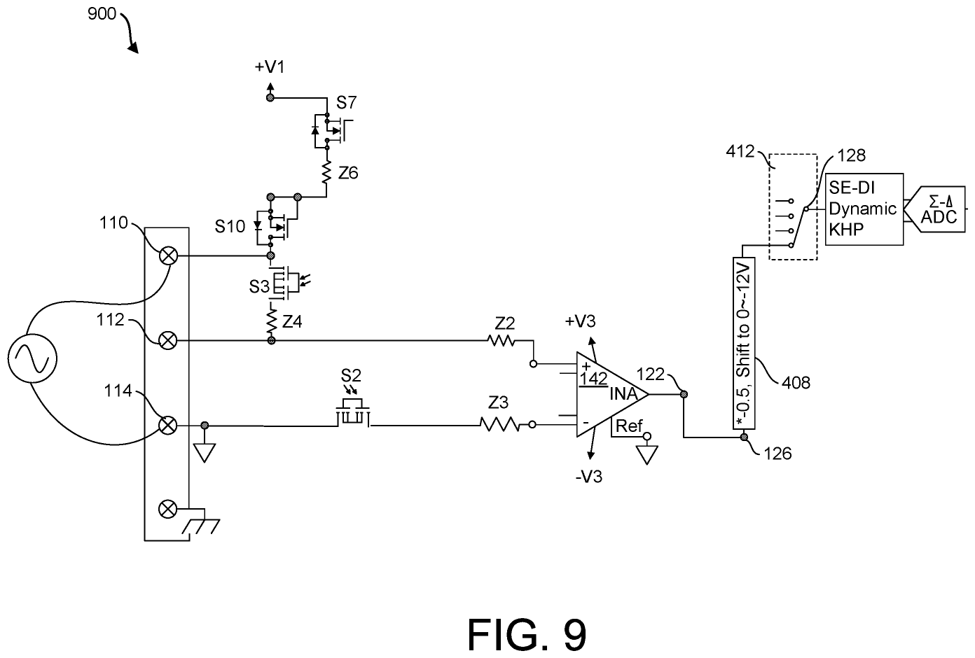

FIG. 9 illustrates an exemplary configuration 900 of the input circuit 102 configured to couple an analog voltage signal source with input voltage with amplitude ranging from a positive value to a negative value (e.g., ±10 V or ±12 V, etc.) to the monitoring system. For example, the analog voltage signal source can be included in a transmitter, a programmable logical controller (PLC), a distributed control system (DCS), etc. In some implementation of the configuration 900, the first input pin 110 and the third input pin 114 are coupled to a DC (direct current) voltage source (e.g., included in analog signal source) to the first input pin 110 relative to the third input pin 114. In some implementations, the power supply circuit 150 is connected to the input circuit 102 by switching on the tenth switch S10. The second electrical path in the power supply circuit 150 is selectively activated by switching the seventh switch S7 on and switching the sixth switch S6 off (which deactivates the first electrical path in the power supply circuit 150). The current supply circuit 160 is disconnected from the first input pin 110 and the second input pin 112 (e.g., by switching the eleventh switch S11 and the twelfth switch S12 off). Furthermore, the second switch S2 and the third switch S3 are switched on, and the first switch S1, the fourth switch S4, the fifth switch S5, eighth switch S8, and the ninth switch S9 are switched off.

The output circuit 104 can be reconfigured to modify the intermediate output signal of the input circuit 102 coupled to the analog voltage signal source. For example, the first multiplexer switch 412 can be configured to electrically couple the fifth input pin 126 to the third output pin via the third level shifter 408. The third level shifter 408 is configured to generate a fourth level shifted voltage signal (e.g., as described above) based on a fourth voltage signal generated by the second operational amplifier 142 (e.g., at the second output pin 122). The fourth level shifted voltage signal is transmitted to the third output pin 128. The second multiplexer switch 414 can be configured to be switched off and disconnect the fifth input pin 126 with the fourth output pin 130.

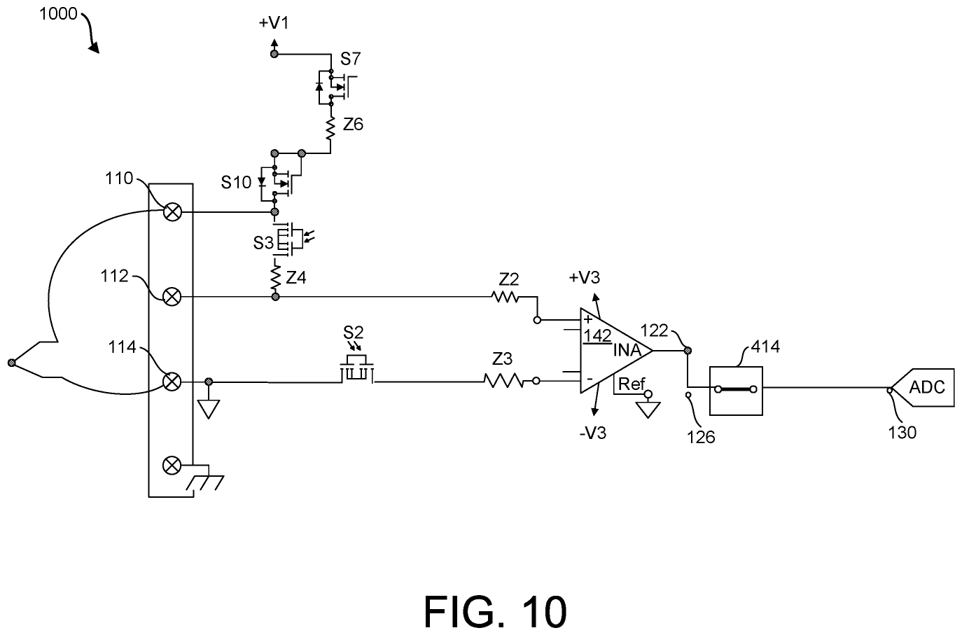

FIG. 10 illustrates an exemplary configuration 1000 of the input circuit 102 configured to couple a thermocouple sensor to the monitoring system. In some implementation of the configuration 1000, the first input pin 110 and the third input pin 114 are coupled to a thermocouple sensor (e.g., with input voltage range of reaching to 21.846 mV for J type thermocouple sensor, 28.943 mV for E type thermocouple sensor, 20.869 mV for T type thermocouple sensor, 16.395 mV for K type thermocouple sensor and 3.26 mV for S type thermocouple sensor, etc.). In some implementations, the power supply circuit 150 can be connected to the input circuit 102 by switching the tenth switch S10 on. The second electrical path in the power supply circuit 150 can be selectively activated by switching the seventh switch S7 on and by switching the sixth switch S6 off (which deactivates the first electrical in the power supply circuit 150). The current supply circuit 160 can be disconnected from the first input pin 110 and the second input pin 112 (e.g., by switching the eleventh switch S11 and the twelfth switch S12 off). Furthermore, the second switch S2 and the third switch S3 are switched on, and the first switch S1, the fourth switch S4, the fifth switch S5, eighth switch S8, and the ninth switch S9 (not shown in FIG. 10) are switched off.

The output circuit 104 can be reconfigured to modify the intermediate output signal of the input circuit 102 coupled to the thermal couple sensor. For example, the first multiplexer switch 412 is switched off (e.g., to disconnect the fourth input pin 124 or fifth input pin 126 from the third output pin 128) and the second multiplexer switch 414 is switched on. The second multiplexer switch 414 is configured to electrically couple the fifth input pin 126 to the fourth output pin 130 pin.

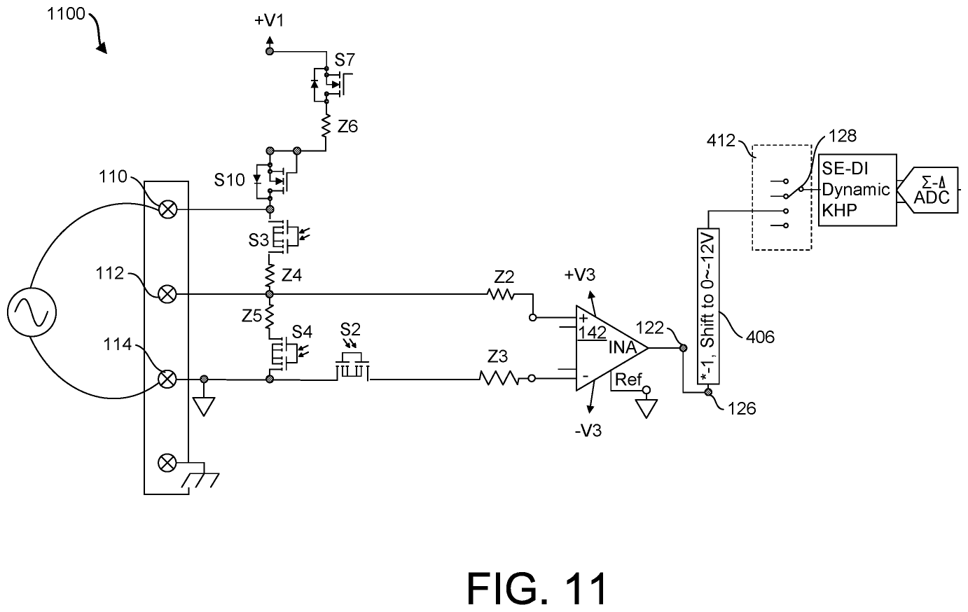

FIG. 11 illustrates an exemplary configuration 1100 of the input circuit 102 configured to couple an analog voltage signal source (e.g., with input range of 0 Volts to 24 Volts) to the monitoring system. The voltage signal source can be included in a transmitter, a programmable logical controller (PLC), a distributed control system (DCS), etc. In some implementation of the configuration 1100, the first input pin 110 and the third input pin 114 are coupled to a DC (direct current) voltage source (e.g., included in analog voltage signal source). In some implementations, the power supply circuit 150 is connected to the input circuit 102 by switching on the tenth switch S10. The second electrical path in the power supply circuit 150 is selectively activated by switching the seventh switch S7 on and switching the sixth switch S6 off (which deactivates the first electrical path in the power supply circuit 150). The current supply circuit 160 is disconnected from the first input pin 110 and the second input pin 112 (e.g., by switching the eleventh switch S11 and the twelfth switch S12 off).. Furthermore, the second switch S2, the third switch S3 and the fourth switch S4 are switched on, and the first switch S1, the fifth switch S5, eighth switch S8, and the ninth switch S9 are switched off.

The output circuit 104 can be reconfigured to modify the intermediate output signal of the input circuit 102 coupled to the analog voltage signal source. For example, the first multiplexer switch 412 can be configured to electrically couple the fifth input pin 126 to the third output pin via the second level shifter 406. The second level shifter 406 is configured to generate a fifth level shifted voltage signal (e.g., as described above) based on a fifth voltage signal generated by the second operational amplifier 142 (e.g., at the second output pin 122). The fifth level shifted voltage signal is transmitted to the third output pin 128. The second multiplexer switch 414 can be configured to be switched off and disconnect the fifth input pin 126 with the fourth output pin 130.

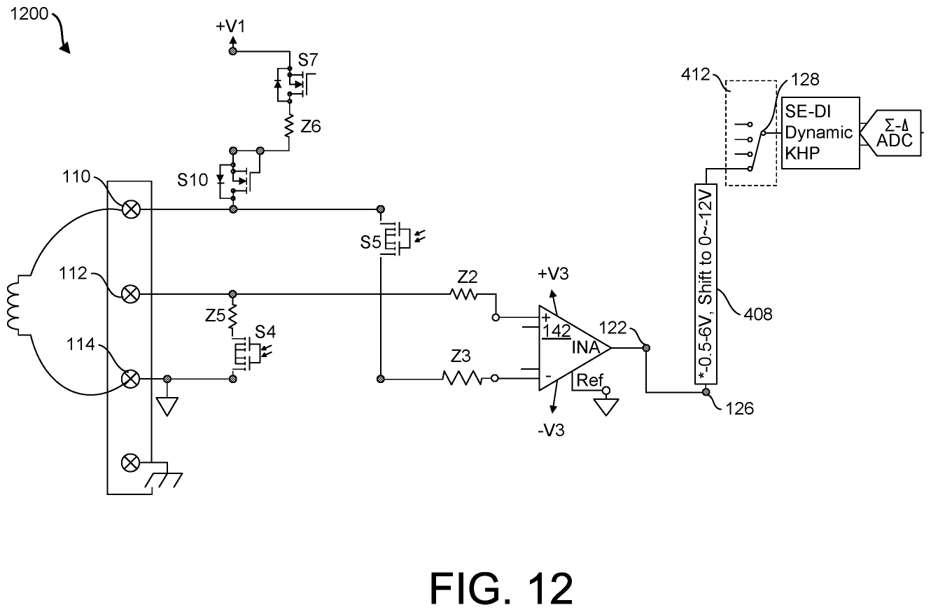

FIG. 12 illustrates an exemplary configuration 1300 of the input circuit 102 configured to couple a magnetic pick up sensor (or a tachogenerator) to the monitoring system. In some implementation of the configuration 1300, the first input pin 110 and the third input pin 114 are coupled to a magnetic pick up sensor (e.g., having an AC input range o+/−125)Vp. . In some implementations, the power supply circuit 150 is connected to the input circuit 102 by switching the tenth switch S10 on. The second electrical path in the power supply circuit 150 is selectively activated by switching the seventh switch S7 on and switching the sixth switch S6 off (which deactivates the first electrical path in the power supply circuit 150). The current supply circuit 160 can be disconnected from the first input pin 110 and the second input pin 112 (e.g., by switching the eleventh switch S11 and the twelfth switch S12 off). Furthermore, the second switch S2, the third switch S3 and the fourth switch S4 are switched on, and the first switch S1, the fifth switch S5, eighth switch S8, and the ninth switch S9 (not shown in FIG. 11) are switched off.

The output circuit 104 can be reconfigured to modify the intermediate output signal of the input circuit 102 coupled to the magnetic pick up sensor. For example, the first multiplexer switch 412 can be configured to electrically couple the fifth input pin 126 to the third output pin via the third level shifter 408. The third level shifter 408 is configured to generate a sixth level shifted voltage signal (e.g., as described above) based on a sixth voltage signal generated by the second operational amplifier 142 (e.g., at the second output pin 122). The third level shifted voltage signal is transmitted to the third output pin 128. The second multiplexer switch 414 can be configured to be switched off and disconnect the fifth input pin 126 with the fourth output pin 130.

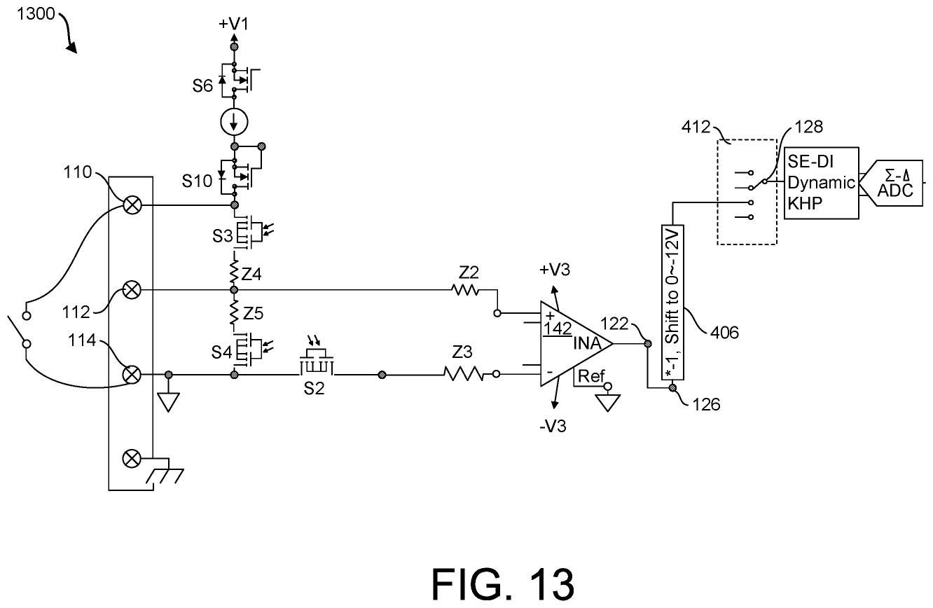

FIG. 13 illustrates an exemplary configuration 1300 of the input circuit 102 configured to couple a proximity switch sensor to the monitoring system. The proximity switch sensor can be coupled to the input circuit 102 via the first input pin 110 and the third input pin 114. In some implementations, the power supply circuit 150 is connected to the input circuit 102 by switching on the tenth switch S10. The first electrical path in the power supply circuit 150 can be selectively activated by switching the sixth switch S6 on and switching the seventh switch S7 off (which deactivates the second electrical path in the power supply circuit 150). The current supply circuit 160 can be disconnected from the first input pin 110 and the second input pin 112 (e.g., by switching the eleventh switch S11 and the twelfth switch S12 off). Furthermore, the first switch S1, the fifth switch S5, the seventh switch S7, the eighth switch S8 and the ninth switch S9 are switched off, and the second switch S2, the third switch S3, and the fourth switch S4 are switched on.

The output circuit 104 can be reconfigured to modify the intermediate output signal of the input circuit 102 coupled to the analog signal source. For example, the first multiplexer switch 412 can be configured to electrically couple the fifth input pin 126 to the third output pin 128 via the second level shifter 406. The second level shifter 406 is configured to generate a seventh level shifted voltage signal (e.g., as described above) based on a seventh voltage signal generated by the second operational amplifier 142. The seventh level shifted voltage signal is transmitted to the third output pin 128. The second multiplexer switch 414 can be configured to be switched off and disconnect the fifth input pin 126 with the fourth output pin 130.

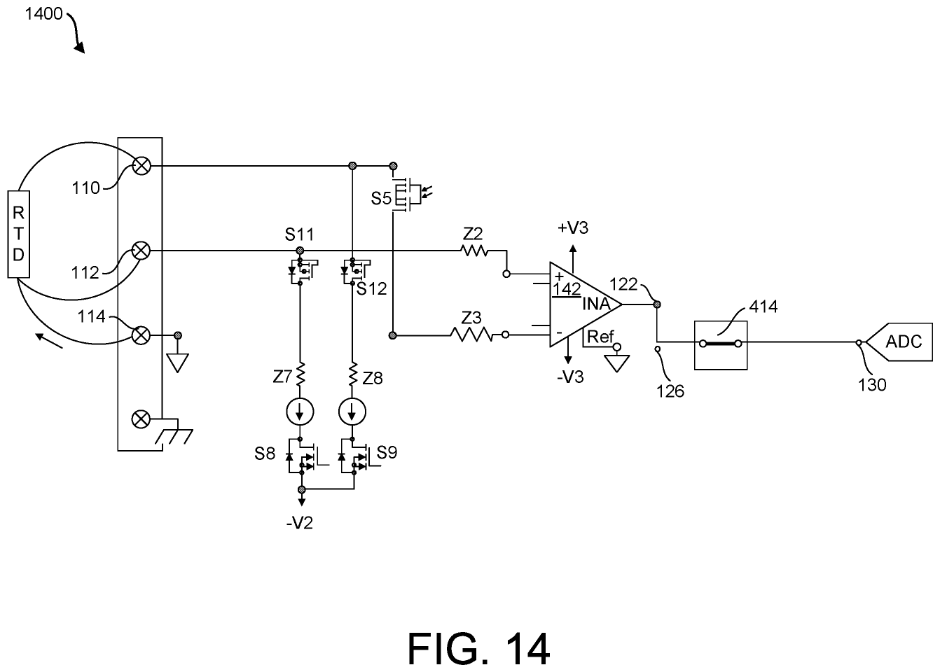

FIG. 14 illustrates an exemplary configuration 1400 of the input circuit 102 configured to couple to a 3-wire resistance temperature detector (RTD) to the monitoring system. In some implementation of the configuration 1400, the first input pin 110, the second input pin 112 and the third input pin 114 are coupled to the 3-wire RTD. The 3-wire RTD can be configured to generate a constant current indicative of a temperature measurement. The power supply circuit 150 can be disconnected from the first input pin 110 (e.g., by switching the tenth switch S10 off). The current supply circuit 160 is connected to the first input pin 110 by switching on ninth switch S9 and the twelfth switch S12 (which activates the first electrical path in the current supply circuit 160), and to the second input pin 112 by switching on the eight switch S8 and the eleventh switch S11 (which activates the second electrical path in the current supply circuit 160). Furthermore, the first switch S1, the second switch S2, the third switch S3, the fourth switch S4, the sixth switch S6, the seventh switch S7 and the tenth switch S10 (not shown in FIG. 14) are switched off, and the fifth switch S5 is switched on.

The output circuit 104 can be reconfigured to modify the intermediate output signal of the input circuit 102 coupled to the 3-wire RTD. For example, the first multiplexer switch 412 is switched off (e.g., to disconnect the fourth input pin 124 or fifth input pin 126 from the third output pin 128) and the second multiplexer switch 414 is switched on. The second multiplexer switch 414 is configured to electrically couple the fifth input pin 126 to the fourth output pin 130 pin.

Certain exemplary embodiments will now be described to provide an overall understanding of the principles of the structure, function, manufacture, and use of the systems, devices, and methods disclosed herein. One or more examples of these embodiments are illustrated in the accompanying drawings. Those skilled in the art will understand that the systems, devices, and methods specifically described herein and illustrated in the accompanying drawings are non-limiting exemplary embodiments and that the scope of the present invention is defined solely by the claims. The features illustrated or described in connection with one exemplary embodiment may be combined with the features of other embodiments. Such modifications and variations are intended to be included within the scope of the present invention. Further, in the present disclosure, like-named components of the embodiments generally have similar features, and thus within a particular embodiment each feature of each like-named component is not necessarily fully elaborated upon

The techniques described herein can be implemented using one or more modules. As used herein, the term “module” refers to computing software, firmware, hardware, and/or various combinations thereof. At a minimum, however, modules are not to be interpreted as software that is not implemented on hardware, firmware, or recorded on a non-transitory processor readable recordable storage medium (i.e., modules are not software per se). Indeed “module” is to be interpreted to always include at least some physical, non-transitory hardware such as a part of a processor or computer. Two different modules can share the same physical hardware (e.g., two different modules can use the same processor and network interface). The modules described herein can be combined, integrated, separated, and/or duplicated to support various applications. Also, a function described herein as being performed at a particular module can be performed at one or more other modules and/or by one or more other devices instead of or in addition to the function performed at the particular module. Further, the modules can be implemented across multiple devices and/or other components local or remote to one another. Additionally, the modules can be moved from one device and added to another device, and/or can be included in both devices.

Approximating language, as used herein throughout the specification and claims, may be applied to modify any quantitative representation that could permissibly vary without resulting in a change in the basic function to which it is related. Accordingly, a value modified by a term or terms, such as “about” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

What is claimed is:

1. An interface circuit comprising:
an input circuit comprising:
a first input pin, a second input pin and a third input pin;
a first operational amplifier comprising:
a first output pin,
a first non-inverting input pin electrically coupled to the first input pin via a first impedance and a first switch,
a first inverting input pin coupled to the first output pin;
a second operational amplifier comprising:
a second output pin,
a second non-inverting input electrically coupled to the second input pin via a second impedance;
a second inverting input pin electrically coupled to the third input pin via a third impedance and a second switch,
wherein the first input pin and the second input pin are electrically coupled via a third switch and a fourth impedance, wherein the second input pin and the third input pin are electrically coupled via a fifth impedance and a fourth switch, and wherein a fifth switch is located between the first input pin and a first node where the second switch and the third impedance are coupled.

2. The interface circuit of claim 1, further comprising an output circuit including a fourth input pin coupled to the first output pin, a fifth input pin coupled to the second output pin, a third output pin, a fourth output pin, a first multiplexer switch, and a plurality of level shifter circuits,
wherein the first multiplexer switch is configured to electrically couple one of:
the fourth input pin to the third output pin via a first level shifter of the plurality of level shifters;
the fifth input pin to the third output pin via a direct connector;
the fifth input pin to the third output pin via a second level shifter of the plurality of level shifters;
the fifth input pin to the third output pin via a third level shifter of the plurality of level shifters.

3. The interface circuit of claim 2, wherein the first input pin and the third input pin are coupled to a negative proximity sensor,
wherein the first switch and the fifth switch are turned off, and wherein the second switch, the third switch, and the fourth switch are turned on.

4. The interface circuit of claim 3, wherein the first multiplexer switch is configured to electrically couple the fifth input pin to the third output pin via a direct connector, and
wherein a first voltage signal generated by the second operational amplifier is transmitted from the second output pin of the input circuit to the third output pin of the output circuit via the direct connector.

5. The interface circuit of claim 2, wherein the first input pin and the third input pin are coupled to a positive proximity sensor,
wherein the first switch and the fifth switch are turned off, and wherein the second switch, the third switch, and the fourth switch are turned on.

6. The interface circuit of claim 5, wherein the first multiplexer switch is configured to electrically couple the fifth input pin to the third output pin via the second level shifter,
wherein the second level shifter is configured to generate a second level shifted voltage signal based on a second voltage signal generated by the second operational amplifier, the second level shifted voltage signal transmitted to the third output pin.

7. The interface circuit of claim 2, further comprising a power supply circuit coupled to the first input pin, the power supply circuit including:
a first current source electrically coupled to a voltage source via a sixth switch, and
a sixth impedance electrically coupled to the voltage source via a seventh switch,
wherein the first current source and the sixth impedance are coupled at a second node,
wherein the second node is electrically coupled to the first input via a tenth switch.

8. The interface circuit of claim 7, further comprising a current supply circuit coupled to the first input pin and the second input pin, the current supply circuit including:
a second current source electrically coupled to the first input pin via an eighth impedance and a twelfth switch, and coupled to the ground potential via a ninth switch; and
a third current source electrically coupled to the second input pin via a seventh impedance and an eleventh switch and coupled to a ground potential via an eighth switch.

9. The interface circuit of claim 8, wherein the first input pin and the third input pin are coupled to an acceleration sensor and the second input is coupled to a temperature sensor,
wherein the first switch, the second switch, the sixth switch, the eighth switch and the tenth switch are turned on, and the third switch, the fourth switch, the fifth switch, seventh switch and the ninth switch are turned off.

10. The interface circuit of claim 9, wherein the first multiplexer switch is configured to electrically couple the fourth input pin to the third output pin via the first level shifter,
wherein the first level shifter is configured to generate a first level shifted voltage signal based on a first voltage signal generated by the first operational amplifier, the first level shifted voltage signal transmitted to the third output pin,
wherein a second multiplexer switch is configured to electrically couple the fifth input pin to the fourth output pin.

11. The interface circuit of claim 8, wherein the first input pin is configured to receive a positive voltage signal relative to the third input pin;,
wherein the second switch, the third switch, the seventh switch and the tenth switch are turned on, and the first switch, the fourth switch, the fifth switch, sixth switch, eighth switch, the ninth switch, eleventh switch and twelfth switch are turned off.

12. The interface circuit of claim 11, wherein the first multiplexer switch is configured to electrically couple the fourth input pin to the third output pin via the second level shifter,
wherein the second level shifter is configured to generate a third level shifted voltage signal based on a third voltage signal generated by the second operational amplifier, the third level shifted voltage signal transmitted to the third output pin.

13. The interface circuit of claim 7, wherein the first input pin and the third input pin are coupled to an analog DC (direct current) voltage source configured to generate a voltage signalaasource configured to apply one of a positive bias or a negative bias to the first input pin relative to the third input pin,
wherein the first switch, the fourth switch, the fifth switch, the sixth switch, the eighth switch and the ninth switch are turned off; wherein the second switch, the third switch, the seventh switch and the tenth switch are turned on.

14. The interface circuit of claim 13, wherein the first multiplexer switch is configured to electrically couple the fifth input pin to the third output pin via the third level shifter,
wherein the third level shifter is configured to generate a fourth level shifted voltage signal based on a fourth voltage signal generated by the second operational amplifier, the fourth level shifted voltage signal transmitted to the third output pin.

15. The interface circuit of claim 13, wherein the first multiplexer switch is turned off and the fifth input pin is electrically coupled to the fourth output pin via a direct connector.

16. The interface circuit of claim 7, wherein the first input pin and the third input pin are coupled to an analog DC (direct current) voltage source configured to apply a positive bias to the first input pin relative to the third input pin,
wherein the first switch, the fifth switch, the sixth switch, the eighth switch and the ninth switch are turned off; wherein the second switch, the third switch, the fourth switch, the seventh switch and the tenth switch are turned on.

17. The interface circuit of claim 15, wherein the first multiplexer switch is configured to electrically couple the fifth input pin to the third output pin via the second level shifter,
wherein the second level shifter is configured to generate a fifth level shifted voltage signal based on a fifth voltage signal generated by the second operational amplifier, the fifth level shifted voltage signal transmitted to the third output pin.

18. The interface circuit of claim 7, wherein the first input pin and the third input pin are coupled to a magnetic pick up sensor,
wherein the first switch, the second switch, the third switch, the sixth switch, the eighth switch and the ninth switch are turned off, wherein the fourth switch, the fifth switch, seventh switch and the tenth switch are turned on.

19. The interface circuit of claim 18, wherein the first multiplexer switch is configured to electrically couple the fifth input pin to the third output pin via the third level shifter,
wherein the third level shifter is configured to generate a sixth level shifted voltage signal based on a sixth voltage signal generated by the second operational amplifier, the sixth level shifted voltage signal transmitted to the third output pin.

20. The interface circuit of claim 7, wherein the first input pin and the third input pin are coupled to a proximity switch,
wherein the first switch, the fifth switch, the seventh switch, the eighth switch and the ninth switch are turned off, wherein the second switch, the third switch, the fourth switch, the sixth switch and the tenth switch are turned on.

21. The interface circuit of claim 20, wherein the first multiplexer switch is configured to electrically couple the fifth input pin to the third output pin via the second level shifter,
wherein the second level shifter is configured to generate a seventh level shifted voltage signal based on a seventh voltage signal generated by the second operational amplifier, the seventh level shifted voltage signal transmitted to the third output pin.

22. The interface circuit of claim 8, wherein the first input pin, the second input pin and the third input pin are coupled to a resistance temperature detector,
wherein the first switch, the second switch, the third switch, the fourth switch, the sixth switch, the seventh switch and the tenth switch are turned off, wherein the fifth switch, the eighth switch, the ninth switch, the eleventh switch and the twelfth switch are turned on.

23. The interface circuit of claim 22, wherein the first multiplexer switch is turned off and the fifth input pin is electrically coupled to the fourth output pin via a direct connector.

24. A system comprising:
one or more sensors configured to detect one or more operating parameters of an industrial system;
an interface circuit configured to couple to the one or more sensors and receive one or more sensor signals, wherein a first sensor signal of the one or more sensor signals is indicative of a first operating parameters of the one or more operating parameters, wherein the interface circuit includes:
an input circuit comprising:
a first input pin, a second input pin and a third input pin,
a first operational amplifier comprising:
a first output pin,
a first non-inverting input pin electrically coupled to the first input pin via a first impedance and a first switch,
a first inverting input pin coupled to the first output pin;
a second operational amplifier comprising:
a second output pin,
a second non-inverting input electrically coupled to the second input pin via a second impedance,
a second inverting input pin electrically coupled to the third input pin via a third impedance and a second switch, wherein the first input pin and the second input pin are electrically coupled via a third switch and a fourth impedance, wherein the second input pin and the third input pin are electrically coupled via a fifth impedance and a fourth switch, and wherein a fifth switch is located between the first input pin and a first node where the second switch and the third impedance are coupled; and
a monitoring system configured to receive one or more conditioned signals from the interface circuit, wherein a first conditioned signal of the one or more conditioned signal is indicative of a first sensor signal.

25. The system of claim 24, wherein the interface circuit further includes an output circuit including:
a fourth input pin coupled to the first output pin, a fifth input pin coupled to the second output pin, a third output pin, a fourth output pin, a first multiplexer switch, and a plurality of level shifter circuits,
wherein the first multiplexer switch is configured to electrically couple one of:
the fourth input pin to the third output pin via a first level shifter of the plurality of level shifters;
the fifth input pin to the third output pin via a direct connector;
the fifth input pin to the third output pin via a second level shifter of the plurality of level shifters;
the fifth input pin to the third output pin via a third level shifter of the plurality of level shifters.

26. A method comprising:
detecting, by one or more sensors, one or more operating parameters of an industrial system;
receiving, by an interface circuit coupled to the one or more sensors, one or more sensor signals from the one or more sensors, wherein a first sensor signal of the one or more signals is indicative of a first operating parameters of the one or more operating parameters, wherein the interface circuit includes:
an input circuit comprising:
a first input pin, a second input pin and a third input pin,
a first operational amplifier comprising:
a first output pin,
a first non-inverting input pin electrically coupled to the first input pin via a first impedance and a first switch,
a first inverting input pin coupled to the first output pin;
a second operational amplifier comprising:
a second output pin,
a second non-inverting input electrically coupled to the second input pin via a second impedance,
a second inverting input pin electrically coupled to the third input pin via a third impedance and a second switch, wherein the first input pin and the second input pin are electrically coupled via a third switch and a fourth impedance, wherein the second input pin and the third input pin are electrically coupled via a fifth impedance and a fourth switch, and wherein a fifth switch is located between the first input pin and a first node where the second switch and the third impedance are coupled; and
providing, by the interface circuit, one or more conditioned signals to a monitoring system, wherein a first conditioned signal of the one or more conditioned signal is indicative of a first sensor signal.
